(19) United States
(12) Patent Application Publication
(10) Pub. No.: US 2013/0240881 A1
(43) Pub. Date: Sep. 19, 2013

(54) COATING LIQUID FOR FORMING METAL OXIDE THIN FILM, METAL OXIDE THIN FILM, FIELD EFFECT TRANSISTOR, AND METHOD FOR PRODUCING THE FIELD EFFECT TRANSISTOR

(71) Applicants: Yuki Nakamura, Tokyo (JP); Naoyuki Ueda, Kanagawa (JP); Yukiko Abe, Kanagawa (JP); Yuji Sone, Kanagawa (JP)

(72) Inventors: Yuki Nakamura, Tokyo (JP); Naoyuki Ueda, Kanagawa (JP); Yukiko Abe, Kanagawa (JP); Yuji Sone, Kanagawa (JP)

(73) Assignee: Ricoh Company, Ltd., Tokyo (JP)

(21) Appl. No.: 13/989,975

(22) PCT Filed: Nov. 22, 2011
(86) PCT No.: PCT/JP2011/077444

§ 371 Date: May 28, 2013

(30) Foreign Application Priority Data
Nov. 29, 2010 (JP) 2010-265261
Jun. 15, 2011 (JP) 2011-133479
Nov. 17, 2011 (JP) 2011-251495

(51) Int. Cl. H01L 29/786

(52) U.S. Cl. CPC H01L 29/7869
USPC 257/43; 252/519.3; 252/519.51

(57) ABSTRACT

A coating liquid for forming a metal oxide thin film, the coating liquid including: an inorganic indium compound; at least one of an inorganic magnesium compound and an inorganic zinc compound; and a glycol ether.

### TECHNICAL FIELD

The present invention relates to a coating liquid for forming a metal oxide thin film, a metal oxide thin film, a field effect transistor and a method for producing the field effect transistor.

### BACKGROUND ART

Conventionally, metal oxides such as antimony-doped tin oxide (ATO) and tin-doped indium oxide (ITO) have been used, in the form of a transparent conductive film, as electrodes of display elements such as liquid crystal display elements and electroluminescence display elements. They are also used for resistance heating elements for preventing tarnishing or freezing of windows of automobiles, airplanes and buildings.

In recent years, it has been found that oxide semiconductors such as metal oxides ZnO, In₂O₃ and In—Ga—Zn—O are semiconductors exhibiting higher carrier mobility than that of amorphous silicon. Development has actively been made on field effect transistors (FETs; Field Effect Transistors) using these oxide semiconductors as their active layers.

In general, the method for forming a thin film of such metal oxides is, for example, a vacuum vapor deposition method and a sputtering method.

However, these methods require complex, expensive apparatuses. In addition, they are difficult to form a thin film having a large area.

Thus, in an attempt to achieve a method by which a thin film having a large area can be formed in a simpler manner, there have been proposed a coating liquid prepared by dissolving in an organic solvent or the like an inorganic metal compound or an organic metal compound and adding to the resultant solution other metals as an activator for imparting higher conductivity thereto; and a coating method using this coating liquid.

For example, for the purpose of forming a thin film having high conductivity and transmittance, there has been proposed a transparent conductive film-forming composition containing an inorganic indium compound, a magnesium compound, and an organic compound able to coordinate with indium (see PTL 1). Also, there has been proposed a transparent conductive film-forming composition containing indium nitrate, a condensate of a polyhydric alcohol, and an activator which are dissolved in an organic solvent (see PTL 2).

However, these proposed techniques are techniques relating to compositions for forming a transparent conductive film, and the obtained transparent conductive films cannot satisfactorily function as an active layer of a field effect transistor and their applications are problematically limited.

Furthermore, there has been proposed a metal oxide precursor solution containing an inorganic metal salt, serving as a metal oxide precursor, dissolved in water or ethanol, serving as a solvent; and a method for producing an oxide semiconductor by coating a base with the metal oxide precursor solution (see PTL 3). The oxide semiconductor obtained by this proposed technique has been studied for an active layer of a field effect transistor.

However, when the metal oxide precursor solution obtained by this proposed technique is coated on a base, the solution (coating liquid) thinly spread on the base, resulting in that the obtained oxide semiconductor is low in shape accuracy.

Therefore, at present, demand has arisen for the provision of the following: a coating liquid for forming a metal oxide thin film (or a metal oxide thin film-coating liquid) which can form a metal oxide thin film with a desired volume resistivity in a simple manner so as to have a large area and can a metal oxide of a desired shape with high accuracy; a metal oxide thin film obtained from the metal oxide thin film-coating liquid; a field effect transistor containing an active layer of an oxide semiconductor formed through coating of the metal oxide thin film-coating liquid; and a method for producing the field effect transistor.

### CITATION LIST

### Patent Literature

PTL 1 Japanese Patent Application Laid-Open (JP-A) No. 06-96619
PTL 2 JP-A No. 07-320541
PTL 3 JP-A No. 2009-177149

### SUMMARY OF INVENTION

### Technical Problem

The present invention aims to solve the existing problems pertinent in the art and achieve the following objects. Specifically, an object of the present invention is to provide: a metal oxide thin film-coating liquid which can form a metal oxide thin film with a desired volume resistivity in a simple manner so as to have a large area and can a metal oxide of a desired shape with high accuracy; a metal oxide thin film obtained from the metal oxide thin film-coating liquid; a field effect transistor containing an active layer of an oxide semiconductor formed through coating of the metal oxide thin film-coating liquid; and a method for producing the field effect transistor.

### Solution to Problem

Means for solving the above problems are as follows.

<1> A coating liquid for forming a metal oxide thin film, the coating liquid including:

an inorganic indium compound;

at least one of an inorganic magnesium compound and an inorganic zinc compound; and

a glycol ether.

<2> A metal oxide thin film obtained by a method including:

coating a coating object with the coating liquid for forming a metal oxide thin film according to <1>;

drying the coating object which has been coated with the coating liquid; and

baking the dried coating object to form the metal oxide thin film thereover.

<3> A field effect transistor including:

a gate electrode configured to apply gate voltage,

a source electrode and a drain electrode which are configured to take out current,

an active layer formed of an oxide semiconductor and disposed between the source electrode and the drain electrode, and

a gate insulating layer formed between the gate electrode and the active layer,

wherein the oxide semiconductor is formed through coating of the coating liquid for forming a metal oxide thin film according to <1>.

<4> A method for producing a field effect transistor, the method including:

forming a gate electrode on a base,

forming a gate insulating layer on the gate electrode;

forming a source electrode and a drain electrode on the gate insulating layer so that the source electrode and the drain electrode are spaced from each other to form a channel region therebetween; and

forming an active layer formed of an oxide semiconductor on the gate insulating layer in the channel region between the source electrode and the drain electrode,

wherein the forming the active layer is coating the gate insulating layer with the coating liquid for forming a metal oxide thin film according to <1>, to thereby form the active layer of the oxide semiconductor.

<5> A method for producing a field effect transistor, the method including:

forming a source electrode and a drain electrode on a base so that the source electrode and the drain electrode are spaced from each other to form a channel region therebetween;

forming an active layer formed of an oxide semiconductor on the base in the channel region between the source electrode and the drain electrode;

forming a gate insulating layer on the active layer; and

forming a gate electrode on the gate insulating layer,

wherein the forming the active layer is coating the base with the coating liquid for forming a metal oxide thin film according to <1>, to thereby form the active layer of the oxide semiconductor.

### Advantageous Effects of Invention

The present invention can provide: a metal oxide thin film-coating liquid which can form a metal oxide thin film with a desired volume resistivity in a simple manner so as to have a large area and can a metal oxide of a desired shape with high accuracy; a metal oxide thin film obtained from the metal oxide thin film-coating liquid; a field effect transistor containing an active layer of an oxide semiconductor formed through coating of the metal oxide thin film-coating liquid; and a method for producing the field effect transistor. These can solve the above existing problems.

### BRIEF DESCRIPTION OF DRAWINGS

FIG. 1 is a schematic, structural view of one exemplary field effect transistor of a bottom gate/bottom contact type.

FIG. 2 is a schematic, structural view of one exemplary field effect transistor of a bottom gate/top contact type.

FIG. 3 is a schematic, structural view of one exemplary field effect transistor of a top gate/bottom contact type.

FIG. 4 is a schematic, structural view of one exemplary field effect transistor of a top gate/top contact type.

FIG. 5A is a first step of one exemplary method of the present invention for producing a field effect transistor.

FIG. 5B is a second step of one exemplary method of the present invention for producing a field effect transistor.

FIG. 5C is a third step of one exemplary method of the present invention for producing a field effect transistor.

FIG. 5D is a fourth step of one exemplary method of the present invention for producing a field effect transistor.

FIG. 6 is a schematic view of a state where the metal oxide thin film-coating liquid shows good coatability.

FIG. 7 is a schematic view of a state where the metal oxide thin film-coating liquid shows poor coatability.

FIG. 8 is a graph of the relationship between gate voltage Vgs and source-drain current Ids of a field effect transistor produced in Example 1.

FIG. 9 is a graph of the relationship between volume resistivity and the ratio [B/(A+B)] in each of the coating liquids of Examples 1 to 27 where A denotes the number of indium ions and B denotes the sum of the number of magnesium ions and the number of zinc ions.

FIG. 10 is a graph of the relationship between the viscosity and the glycol ether-diol ratio of the metal oxide thin film-coating liquid.

### DESCRIPTION OF EMBODIMENTS

### (Coating Liquid for Forming a Metal Oxide Thin Film (Metal Oxide Thin Film-Coating Liquid))

A coating liquid of the present invention for forming a metal oxide thin film contains at least: an inorganic indium compound; at least one of an inorganic magnesium compound and an inorganic zinc compound; and a glycol ether, and preferably contains a diol. If necessary, the coating liquid further contains other ingredients.

Use of the coating liquid for forming a metal oxide thin film can form a metal oxide thin film having an intended volume resistivity.

Notably, by adjusting the conditions of the coating liquid for forming a metal oxide thin film, specifically, the type of a solvent used and the concentration of inorganic compounds (e.g., nitric acid salts), it is possible to control the volume resistivity of the formed metal oxide thin film (e.g., an oxide semiconductor thin film). In addition, the volume resistivity can be controlled by partially replacing the constituent elements of the In—Mg oxide and the In—Zn oxide with other metal elements.

Furthermore, it is also possible to control the volume resistivity by adjusting thermal treatment conditions after coating, specifically, baking temperature, baking time, temperature increasing rate, temperature decreasing rate, atmosphere in baking (gas fraction and pressure).

Moreover, light can be utilized to promote decomposition of materials and proceeding of reaction. It is also effective to optimize the annealing temperature and atmosphere, since the volume resistivity is changed by annealing of the formed film.

### <Inorganic Indium Compound>

The inorganic indium compound is not particularly limited and may be appropriately selected depending on the intended purpose. Examples thereof include indium oxoacids, indium halides, indium hydroxides and indium cyanide.

Examples of the indium oxoacids include indium nitrate, indium sulfate, indium carbonate and indium phosphate.

Examples of the indium halides include indium chloride, indium bromide and indium iodide.

Among them, from the viewpoint of exhibiting high dissolvability to various solvents, preferred are indium oxoacids and indium halides, more preferred are indium nitrate, indium sulfate and indium chloride.

The indium nitrate is not particularly limited and may be appropriately selected depending on the intended purpose. Examples thereof include indium nitrate hydrates. Examples of the indium nitrate hydrates include indium nitrate trihydrate and indium nitrate pentahydrate.

The indium sulfate is not particularly limited and may be appropriately selected depending on the intended purpose. Examples thereof include indium sulfate anhydrates and indium sulfate hydrates. Examples of the indium sulfate hydrates include indium sulfate nonahydrate.

The indium chloride is not particularly limited and may be appropriately selected depending on the intended purpose. Examples thereof include indium chloride hydrates. Examples of the indium chloride hydrates include indium chloride tetrahydrate.

These inorganic indium compounds may be a synthesized product or a commercially available product.

### <Inorganic Magnesium Compound and Inorganic Zinc Compound>

### —Inorganic Magnesium Compound—

The inorganic magnesium compound is not particularly limited and may be appropriately selected depending on the intended purpose. Examples thereof include magnesium oxoacids, magnesium halides, magnesium hydroxides and magnesium cyanide.

Examples of the magnesium oxoacids include magnesium nitrates, magnesium sulfates, magnesium carbonates and magnesium phosphates.

Examples of the magnesium halides include magnesium chloride, magnesium bromide and magnesium iodide.

Among them, from the viewpoint of exhibiting high dissolvability to various solvents, preferred are magnesium oxoacids and magnesium halides, more preferred are magnesium nitrate, magnesium sulfate and magnesium chloride.

The magnesium nitrate is not particularly limited and may be appropriately selected depending on the intended purpose. Examples thereof include magnesium nitrate hydrates. Examples of the magnesium nitrate hydrates include magnesium nitrate trihydrates and magnesium nitrate pentahydrates.

The magnesium sulfate is not particularly limited and may be appropriately selected depending on the intended purpose. Examples thereof include magnesium sulfate hydrates. Examples of the magnesium sulfate hydrates include magnesium sulfate monohydrate and magnesium sulfate heptahydrate.

The magnesium chloride is not particularly limited and may be appropriately selected depending on the intended purpose. Examples thereof include magnesium chloride hydrates. Examples of the magnesium chloride hydrates include magnesium chloride hexahydrate.

These inorganic magnesium compounds may be a synthesized product or a commercially available product.

### —Inorganic Zinc Compound—

The inorganic zinc compound is not particularly limited and may be appropriately selected depending on the intended purpose. Examples thereof include zinc oxoacids, zinc halides, zinc hydroxides and zinc cyanide.

Examples of the zinc oxoacids include zinc nitrate, zinc sulfate, zinc carbonate and zinc phosphate.

Examples of the zinc halides include zinc chloride, zinc bromide and zinc iodide.

Among them, from the viewpoint of exhibiting high dissolvability to various solvents, preferred are zinc oxoacids and zinc halides, more preferred are zinc nitrate, zinc sulfate and zinc chloride.

The zinc nitrate is not particularly limited and may be appropriately selected depending on the intended purpose. Examples thereof include zinc nitrate hydrates. Examples of the zinc nitrate hydrates include zinc nitrate trihydrates and zinc nitrate pentahydrates.

The zinc sulfate is not particularly limited and may be appropriately selected depending on the intended purpose. Examples thereof include zinc sulfate anhydrates and zinc sulfate hydrates. Examples of the zinc sulfate hydrates include zinc sulfate dihydrate and zinc sulfate heptahydrate.

The zinc chloride is not particularly limited and may be appropriately selected depending on the intended purpose. Examples thereof include zinc chloride anhydrates and zinc chloride hydrates. Examples of the zinc sulfate hydrates include zinc chloride dihydrate and zinc chloride tetrahydrate.

These inorganic zinc compounds may be a synthesized product or a commercially available product.

The coating liquid for forming a metal oxide thin film preferably satisfies the following expression (1):

0.25≦[B/(A+B)]≦0.65 Expression (1)

where A denotes the number of indium ions in the coating liquid for forming a metal oxide thin film, and B denotes the sum of the number of magnesium ions and the number of zinc ions in the coating liquid for forming a metal oxide thin film.

The coating liquid for forming a metal oxide thin film that satisfies the above expression (1) can also be called a coating liquid for forming an oxide semiconductor thin film.

It has been known that an indium oxide film formed by the sputtering method has a low resistivity of about 10⁻⁴ Ωcm through addition of tin, zinc, gallium, etc. in an amount of about several percents to about 20%. However, the indium oxide film having such a low volume resistivity cannot function as an active layer of a field effect transistor.

When the coating liquid for forming a metal oxide thin film satisfies the above expression (1), the oxide semiconductor thin film formed through coating of the coating liquid for forming a metal oxide thin film can be made to have such a volume resistivity that the oxide semiconductor thin film can function as an active layer of a field effect transistor.

When the [B/(A+B)] is less than 0.25, the formed oxide semiconductor thin film becomes too low in volume resistivity. When this oxide semiconductor thin film is used as an active layer of a field effect transistor, the active layer is always in a conduction state regardless of application of gate voltage; i.e., the formed field effect transistor cannot function as a transistor. Whereas when the [B/(A+B)] exceeds 0.65, the formed oxide semiconductor thin film becomes too high in volume resistivity. When this oxide semiconductor thin film is used as an active layer of a field effect transistor, the formed field effect transistor becomes low in on/off ratio; i.e., does not show good transistor characteristics.

When an oxide semiconductor thin film is used as an active layer of a field effect transistor used for a drive circuit of a display, the oxide semiconductor thin film is required to have high carrier mobility and so-called normally-off characteristics. In order to realize high carrier mobility and normally-off characteristics, the volume resistivity of the oxide semiconductor thin film is preferably adjusted to fall within a range of 10⁻² Ωcm to 10⁹ Ω·cm.

When the volume resistivity of the metal oxide thin film is high, it may be difficult to realize high carrier mobility in the state of ON controlled by gate voltage. Thus, the volume resistivity of the metal oxide thin film is more preferably 10⁶ Ω·cm or lower.

When the volume resistivity of the metal oxide thin film is low, it may be difficult to lower Ids (drain-source current) in the state of OFF controlled by gate voltage. Thus, the volume resistivity of the metal oxide thin film is more preferably 10⁻¹ Ωcm or higher.

The volume resistivity ρ (Ωcm) of the metal oxide thin film is expressed by the following equation (2):

ρ=1/nQμ Equation (2)

where Q (C) denotes a carrier charge, n denotes a carrier density (carriers/m³) and μ denotes a carrier mobility (m²/V/s).

Thus, these n, Q and μ can be changed to control the volume resistivity.

One specific method for controlling the volume resistivity of the metal oxide thin film is a method in which the carrier density is changed by adjusting the amount of oxygen in the film (density of oxygen defects).

The coating liquid for forming a metal oxide thin film satisfies the above expression (1) to control the volume resistivity, and can form an oxide semiconductor thin film effectively used as an active layer of a field effect transistor.

It is most effective that the coating liquid for forming a metal oxide thin film is made to satisfy the above expression (1), as the method for controlling the volume resistivity of an oxide semiconductor thin film formed therefrom.

### <Glycol Ether>

The glycol ether thoroughly dissolves the above inorganic indium compounds (especially indium nitrate), the above inorganic magnesium compounds (especially magnesium nitrate), the above inorganic zinc compounds (especially zinc nitrate), and the resultant solution has high stability. Thus, use of the glycol ether in the coating liquid for forming a metal oxide thin film can form a metal oxide thin film (e.g., an oxide semiconductor thin film) having high uniformity and less defects.

Also, when the glycol ether is used in the coating liquid for forming a metal oxide thin film, it is possible to form, with high accuracy, a metal oxide thin film (e.g., an oxide semiconductor thin film) of an intended shape.

The glycol ether is thought to serve as a reducing agent. In—Mg oxide semiconductors and In—Zn oxide semiconductors, which are N-type semiconductors, generate conduction electrons by forming oxygen defects. Thus, by moving the equilibrium to the reduction side, the material can have higher conductivity. The coating liquid for forming a metal oxide thin film contains the glycol ether, and the glycol ether exhibits its reducing action during thermal treatment after coating, to thereby obtain an oxide semiconductor thin film having a lower volume resistivity.

The glycol ether is not particularly limited and may be appropriately selected depending on the intended purpose. Alkylene glycol monoalkyl ethers are preferred. The number of carbon atoms contained in the glycol ether is preferably 3 to 6.

The alkylene glycol monoalkyl ether is preferably at least one selected from among ethylene glycol monoethyl ether, ethylene glycol monomethyl ether, ethylene glycol monopropyl ether, ethylene glycol monoisopropyl ether, ethylene glycol monobutyl ether and ethylene glycol monoisobutyl ether. These alkylene glycol monoalkyl ethers have a boiling point of about 120° C. to about 180° C. and thus are rapidly dried. As a result, the coating liquid for forming a metal oxide thin film becomes difficult to spread. Use of such a preferred compound can decrease the baking temperature to achieve baking for a relatively short period. Also, the metal oxide thin film (e.g., oxide semiconductor thin film) obtained after baking has less impurities and hence has high carrier mobility. As a result, in a graph of the relationship between gate voltage Vgs and source-drain current Ids of a field effect transistor having this oxide semiconductor thin film as an active layer, the gradient in the rising observed upon change from OFF to ON becomes large. In other words, good switching characteristics can be obtained, and the drive voltage for obtaining ON current required is decreased.

These alkylene glycol monoalkyl ethers may be used alone or in combination.

The amount of the glycol ether contained in the coating liquid for forming a metal oxide thin film is not particularly limited and may be appropriately selected depending on the intended purpose. It is preferably 10% by mass to 80% by mass. When it is less than 10% by mass, the above-described effects by the glycol ether cannot be obtained in some cases. Whereas when it is more than 80% by mass, the thickness of the metal oxide thin film (e.g., oxide semiconductor thin film) that can be formed through coating once may become small.

### <Diol>

The coating liquid for forming a metal oxide thin film preferably further contains a diol. In other words, the glycol ether is preferably used in combination with the diol. When the glycol ether and the diol are used in combination, the diol can prevent clogging of inkjet nozzles due to drying of the solvent when the coating liquid is coated by the inkjet method; and the glycol ether can prevent the coating liquid from spreading to unintended portions by rapidly drying the coating liquid attached onto a base. For example, in producing a field effect transistor, it is possible to rapidly dry the coating liquid attached onto a channel to prevent the coating liquid from spreading to the other regions than the channel region.

The glycol ether generally has a low viscosity of about 1.3 cp to about 3.5 cp. Thus, when the glycol ether is appropriately mixed with the diol having a high viscosity, the coating liquid for forming a metal oxide thin film can easily be adjusted in viscosity.

Presumably, the diol coordinates with indium salts, magnesium salts, zinc salts, aluminum salts or gallium salts, to thereby increase thermal stability of the metal salts.

The diol is not particularly limited and may be appropriately selected depending on the intended purpose, but is preferably alkane diols and dialkylene glycols. The number of carbon atoms contained in the diol preferably 2 to 4. The diol having 5 or more carbon atoms has a low volatility and tends to remain in the formed metal oxide thin film (e.g., oxide semiconductor thin film), potentially decreasing the compactness of the metal oxide thin film (e.g., oxide semiconductor thin film) after baking. Then, when the oxide semiconductor thin film is decreased in compactness, its carrier mobility may decrease and the ON current may decrease.

The diol having 2 to 4 carbon atoms has a boiling point of about 180° C. to about 250° C. Thus, it is evaporated during baking after coating of the coating liquid for forming a metal oxide thin film, and difficult to remain in the metal oxide thin film (e.g., oxide semiconductor thin film). Also, since the diol has a viscosity of about 10 cp to about 110 cp, when the coating liquid for forming a metal oxide thin film is coated by the inkjet method, the diol has an effect of preventing spreading upon attachment of the coating liquid onto a substrate, etc.

The diol is preferably at least one selected from diethylene glycol, 1,2-ethanediol, 1,2-propanediol and 1,3-butanediol, in consideration of the baking temperature and the compactness of the baked metal oxide thin film (e.g., oxide semiconductor thin film).

These may be used alone or in combination.

In the coating liquid for forming a metal oxide thin film, the ratio of the amount of the metal salts and the amount of the diol and the glycol ether is not particularly limited and may be appropriately selected depending on the intended purpose. The amount of the metal salts is preferably 0.1 mol to 0.5 mol per 1 L of the diol and the glycol ether. When it is less than 0.1 mol, the thickness of the metal oxide thin film formed after baking becomes too small, potentially making it difficult to form a continuous film. Also, to obtain the thickness required, it is necessary to repeatedly perform coating and drying in some cases. Whereas when the amount of the metal salts is more than 0.5 mol, the tips of the inkjet nozzles may be clogged at higher frequency when the coating liquid is coated by the inkjet method.

### <Other Ingredients>

Examples of the other ingredients include inorganic aluminum compounds and inorganic gallium compounds.

### —Inorganic Aluminum Compound and Inorganic Gallium Compound—

The aluminum contained in the inorganic aluminum compound or the gallium contained in the inorganic gallium compound serve as a dopant replacing the indium site and has an effect of doping holes in the metal oxide thin film (e.g., oxide semiconductor thin film) obtained through coating of the coating liquid for forming a metal oxide thin film.

The inorganic aluminum compound is not particularly limited and may be appropriately selected depending on the intended purpose. Examples thereof include aluminum oxoacids, aluminum halides, aluminum hydroxides and aluminum cyanide.

Examples of the aluminum oxoacids include aluminum nitrate, aluminum sulfate, aluminum carbonate and aluminum phosphate.

Examples of the aluminum halides include aluminum chloride, aluminum bromide and aluminum iodide.

These may be anhydrates or hydrates thereof.

The inorganic gallium compound is not particularly limited and may be appropriately selected depending on the intended purpose.

Examples thereof include gallium oxoacids, gallium halides, gallium hydroxides and gallium cyanide.

Examples of the gallium oxoacids include gallium nitrate, gallium sulfate, gallium carbonate and gallium phosphate.

Examples of the gallium halides include gallium chloride, gallium bromide and gallium iodide.

These may be anhydrates or hydrates thereof.

These may be used alone or in combination.

The amount of the inorganic aluminum compound and the inorganic gallium compound contained in the coating liquid for forming a metal oxide thin film is not particularly limited and may be appropriately selected depending on the intended purpose. The sum (C) of the number of aluminum ions and the number of gallium ions is preferably 1% to 10% relative to the number (A) of indium ions.

### <Method for Forming Coating Liquid for Forming a Metal Oxide Thin Film>

The method for forming the coating liquid for forming a metal oxide thin film is not particularly limited and may be appropriately selected depending on the intended purpose. Examples thereof include a method in which a diol solution of nitric acid salts and a glycol ether solution of nitric acid salts are separately prepared, and the resultant solutions are mixed with each other.

Specifically, the following method is exemplified.

First, indium nitrate (In(NO₃)₃.3H₂O) and magnesium nitrate (Mg(NO₃)₂.6H₂O) are dissolved in a diol to prepare a diol solution of the nitric acid salts. By stirring the diol (e.g., diethylene glycol, 1,2-ethanediol, 1,2-propanediol or 1,3-butanediol), the indium nitrate and the magnesium nitrate can respectively be dissolved to a concentration of 1 mol/L or higher at room temperature. The time required for dissolution can be shortened by heating.

Subsequently, indium nitrate (In(NO₃)₃.3H₂O) and magnesium nitrate (Mg(NO₃)₂.6H₂O) are dissolved in a glycol ether to prepare a glycol ether solution of the nitric acid salts. By stirring the glycol ether (e.g., ethylene glycol monoethyl ether, ethylene glycol monomethyl ether, ethylene glycol monopropyl ether, ethylene glycol monoisopropyl ether, ethylene glycol monobutyl ether or ethylene glycol monoisobutyl ether), the indium nitrate and the magnesium nitrate can respectively be dissolved to a concentration of 1 mol/L or higher at room temperature. The time required for dissolution can be shortened by heating.

Then, the thus-prepared diol solution and glycol ether solution are mixed with each other at a desired mixing ratio.

The coating liquid of the present invention for forming a metal oxide thin film is suitably used as a coating liquid for forming a metal oxide thin film. In particular, the coating liquid for forming a metal oxide thin film (coating liquid for forming an oxide semiconductor thin film) satisfying the above expression (1) is suitably used as a coating liquid for forming an active layer of a field effect transistor.

### [Another Coating Liquid for Forming a Metal Oxide Thin Film]

As an embodiment of another coating liquid for forming a metal oxide thin film different from that of the present invention, there is exemplified a coating liquid for forming an oxide semiconductor thin film containing at least: an inorganic indium compound; at least one of an inorganic magnesium compound and an inorganic zinc compound; and a diol, optionally further containing other ingredients, and satisfying the above expression (1).

The inorganic indium compound, inorganic magnesium compound, inorganic zinc compound and diol in this coating liquid for forming an oxide semiconductor thin film are the same as the inorganic indium compound, inorganic magnesium compound, inorganic zinc compound and diol in the above-described coating liquid for forming a metal oxide thin film. Their preferred embodiments and amounts thereof are also the same as those in the above-described coating liquid for forming a metal oxide thin film.

The other ingredients are preferably the above-described inorganic aluminum compounds, inorganic gallium compounds, etc.

It has been known that an indium oxide film formed by the sputtering method has a low resistivity of about 10⁻⁴ Ω·cm through addition of tin, zinc, gallium, etc. in an amount of about several percents to about 20%. However, the indium oxide film having such a low volume resistivity cannot function as an active layer of a field effect transistor.

When the coating liquid for forming an oxide semiconductor thin film satisfies the above expression (1), the oxide semiconductor thin film formed through coating of the coating liquid for forming an oxide semiconductor thin film can be made to have such a volume resistivity that the oxide semiconductor thin film can function as an active layer of a field effect transistor.

When the [B/(A+B)] is less than 0.25, the formed oxide semiconductor thin film becomes too low in volume resistivity. When this oxide semiconductor thin film is used as an active layer of a field effect transistor, the active layer is always in a conduction state regardless of application of gate voltage; i.e., the formed field effect transistor cannot function as a transistor. Whereas when the [B/(A+B)] exceeds 0.65, the formed oxide semiconductor thin film becomes too high in volume resistivity. When this oxide semiconductor thin film is used as an active layer of a field effect transistor, the formed field effect transistor becomes low in on/off ratio; i.e., does not show good transistor characteristics.

When an oxide semiconductor thin film is used as an active layer of a field effect transistor used for a drive circuit of a display, the oxide semiconductor thin film is required to have high carrier mobility and so-called normally-off characteristics. In order to realize high carrier mobility and normally-off characteristics, the volume resistivity of the oxide semiconductor thin film is preferably adjusted to fall within a range of 10⁻² Ω·cm to 10⁹ Ω·cm.

A coating object (an object to be coated) is coated with this coating liquid for forming an oxide semiconductor thin film (the above another coating liquid for forming a metal oxide thin film), followed by drying and then baking, whereby an oxide semiconductor thin film can be obtained. The coating object, coating method, drying conditions and baking conditions are the same as those in the production of the below-described metal oxide thin film of the present invention.

### (Metal Oxide Thin Film)

A metal oxide thin film of the present invention is obtained by a method including: coating a coating object with the coating liquid of the present invention for forming a metal oxide thin film; drying the coating object which has been coated with the coating liquid; and baking the dried object.

Examples of the metal oxide thin film include an oxide semiconductor thin film.

When the coating liquid for forming a metal oxide thin film used is a coating liquid for forming a metal oxide thin film (a coating liquid for forming an oxide semiconductor thin film) satisfying the above expression (1), the formed oxide semiconductor thin film is suitably used as an active layer of a field effect transistor.

The coating object is not particularly limited and may be appropriately selected depending on the intended purpose. Examples thereof include a glass base and a plastic base.

When the metal oxide thin film is used as an oxide semiconductor thin film serving as an active layer of a field effect transistor, the coating object is, for example, a base or a gate insulating layer. The shape, structure and size of the base are not particularly limited and may be appropriately selected depending on the intended purpose. The material of the base is not particularly limited and may be appropriately selected depending on the intended purpose. Examples of the base include a glass base and a plastic base.

The coating method of the coating liquid is not particularly limited and may be appropriately selected depending on the intended purpose. Examples thereof include a screen printing method, a roll coating method, a dip coating method, a spin coating method, an inkjet method and a nanoimprint method. Among them, the inkjet method and the nanoimprint method are preferred since they can control the amount of the coating liquid attached. As a result, a metal oxide thin film having a desired shape can be obtained. For example, the width of the channel can be formed as designed in the production of a field effect transistor; in other wards, an active layer having a desired shape can be obtained. When the inkjet method or the nanoimprint method is used, the coating liquid can be coated even at room temperature. However, a base (a coating object) is preferably heated to about 40° C. to about 100° C. from the viewpoint of preventing spreading of the coating liquid immediately before coating on a surface of the base.

The conditions under which the drying is performed are not particularly limited and may be appropriately selected depending on the intended purpose, so long as volatile components in the coating liquid for forming a metal oxide thin film can be removed. Notably, in the drying, the volatile components do not have to be removed completely; i.e., the volatile components may be removed to such an extent that they do not inhibit the baking.

The temperature at which the baking is performed is not particularly limited and may be appropriately selected depending on the intended purpose, so long as it is a temperature that is equal to or higher than a temperature at which an oxide of indium, magnesium, zinc, gallium or aluminum is formed and that is equal to or lower than a temperature at which the base (coating object) is deformed. It is preferably 300° C. to 600° C.

The atmosphere in which the baking is performed is not particularly limited and may be appropriately selected depending on the intended purpose. Examples thereof include an atmosphere containing oxygen such as an oxygen atmosphere or an air atmosphere. When an inert gas such as nitrogen gas is used as the atmosphere in which the baking is performed, the amount of oxygen contained in the formed metal oxide thin film (e.g., oxide semiconductor thin film) can be reduced to obtain a metal oxide thin film (e.g., oxide semiconductor thin film) having a low resistivity.

After baking, by further annealing the baked object in an atmosphere of air, inert gas or reducing gas, the metal oxide thin film (e.g., oxide semiconductor thin film) can be further improved in electrical characteristics, reliability and uniformity.

The time for the baking is not particularly limited and may be appropriately selected depending on the intended purpose.

The average thickness of the formed metal oxide thin film (e.g., oxide semiconductor thin film) is not particularly limited and may be appropriately selected depending on the intended purpose. It is preferably 1 nm to 200 nm, more preferably 5 nm to 100 nm.

The application of the metal oxide thin film is not particularly limited and may be appropriately selected depending on the intended purpose. For example, when the metal oxide thin film has a volume resistivity lower than 10⁻² Ω·cm, it can be used as a transparent conductive thin film. When the metal oxide thin film has a volume resistivity of 10⁻² Ω·cm to 10⁹ Ωcm, it can be used as an active layer of a field effect transistor. When the metal oxide thin film has a volume resistivity higher than 10⁹ Ω·cm, it can be used as an antistatic thin film.

### (Field Effect Transistor)

A field effect transistor of the present invention contains at least a gate electrode, a source electrode, a drain electrode, an active layer and a gate insulating layer; and, if necessary, further contains other members.

The field effect transistor of the present invention can be produced by, for example, a method of the present invention for producing a field effect transistor.

### <Gate Electrode>

The gate electrode is not particularly limited and may be appropriately selected depending on the intended purpose, so long as it is an electrode for applying gate voltage.

The material of the gate electrode is not particularly limited and may be appropriately selected depending on the intended purpose. Examples thereof include: metals such as platinum, palladium, gold, silver, copper, zinc, aluminum, nickel, chromium, tantalum, molybdenum and titanium; alloys thereof, and mixtures thereof. Further examples thereof include: conductive oxides such as indium oxide, zinc oxide, tin oxide, gallium oxide and niobium oxide; composite compounds thereof and mixtures thereof.

The average thickness of the gate electrode is not particularly limited and may be appropriately selected depending on the intended purpose. It is preferably 40 nm to 2 μm, more preferably 70 nm to 1 μm.

### <Gate Insulating Layer>

The gate insulating layer is not particularly limited and may be appropriately selected depending on the intended purpose, so long as it is an insulating layer formed between the gate electrode and the active layer.

The material of the gate insulating layer is not particularly limited and may be appropriately selected depending on the intended purpose. Examples thereof include inorganic insulating materials and organic insulating materials.

Examples of the inorganic insulating materials include silicon oxide, aluminum oxide, tantalum oxide, titanium oxide, yttrium oxide, lanthanum oxide, hafnium oxide, zirconium oxide, silicon nitride, aluminum nitride and mixtures thereof.

Examples of the organic insulating materials include polyimides, polyamides, polyacrylates, polyvinyl alcohols and novolac resins.

The average thickness of the gate insulating layer is not particularly limited and may be appropriately selected depending on the intended purpose. It is preferably 50 nm to 3 μm, more preferably 100 nm to 1 μm.

### <Source Electrode and Drain Electrode>

The source electrode or the drain electrode is not particularly limited and may be appropriately selected depending on the intended purpose, so long as it is an electrode for taking out current.

The material of the source electrode or the drain electrode is not particularly limited and may be appropriately selected depending on the intended purpose. Examples thereof include materials which are the same as described above for the gate electrode.

The average thickness of the source electrode or the drain electrode is not particularly limited and may be appropriately selected depending on the intended purpose. It is preferably 40 nm to 2 μm, more preferably 70 nm to 1 μm.

### <Active Layer>

The active layer is an active layer of an oxide semiconductor formed between the source electrode and the drain electrode, and is formed of an oxide semiconductor formed through coating of the coating liquid of the present invention for forming a metal oxide thin film.

The average thickness of the active layer is not particularly limited and may be appropriately selected depending on the intended purpose. It is preferably 1 nm to 200 μm, more preferably 5 nm to 100 μm.

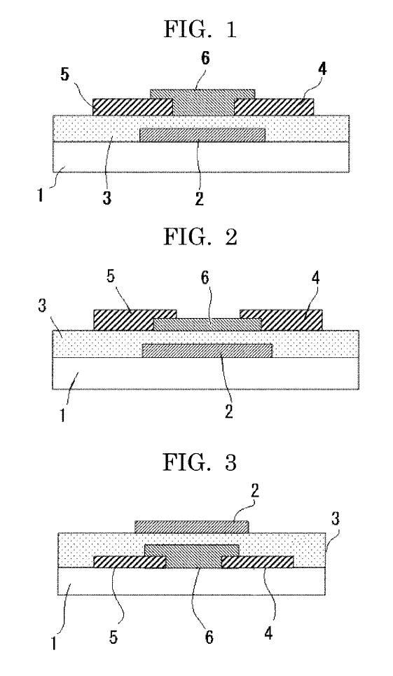

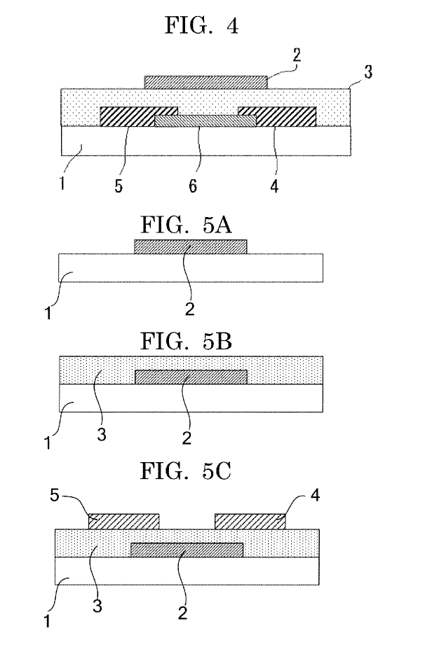

The structure of the field effect transistor is not particularly limited and may be appropriately selected depending on the intended purpose. Examples thereof include a structure of a bottom gate/bottom contact type (FIG. 1), a structure of a bottom gate/top contact type (FIG. 2), a structure of a top gate/bottom contact type (FIG. 3) and a structure of a top gate/top contact type (FIG. 4).

In FIGS. 1 to 4, reference numeral 1 denotes a base, 2 denotes a gate electrode, 3 denotes a gate insulating layer, 4 denotes a source electrode, 5 denotes a drain electrode, and 6 denotes an active layer.

### [Another Field Effect Transistor]

As an embodiment of another field effect transistor different from that of the present invention, there is exemplified a field effect transistor which is the same as the field effect transistor of the present invention except that the above another coating liquid for forming a metal oxide thin film is used instead of the coating liquid of the present invention for forming a metal oxide thin film.

The field effect transistor of the present invention and the another field effect transistor can suitably be used for field effect transistors for use in pixel driving circuits and logic circuits of liquid crystal displays, organic EL displays, electrochromic displays, etc.

### (Method for Producing Field Effect Transistor)

A method of the present invention for producing the field effect transistor (first production method) includes:

a gate electrode-forming step of forming a gate electrode on a base;

a gate insulating layer-forming step of forming a gate insulating layer on the gate electrode;

a source electrode and drain electrode-forming step of forming a source electrode and a drain electrode on the gate insulating layer so that the source electrode and the drain electrode are spaced from each other to form a channel region therebetween; and

an active layer-forming step of forming an active layer of an oxide semiconductor on the gate insulating layer in the channel region between the source electrode and the drain electrode.

Another method of the present invention for producing the field effect transistor (second production method) includes:

a source electrode and drain electrode-forming step of forming a source electrode and a drain electrode on a base so that the source electrode and the drain electrode are spaced from each other to form a channel region therebetween;

an active layer-forming step of forming an active layer of an oxide semiconductor on the base in the channel region between the source electrode and the drain electrode;

a gate insulating layer-forming step of forming a gate insulating layer on the active layer; and

a gate electrode-forming step of forming a gate electrode on the gate insulating layer.

### <First Production Method>

The above first production method will next be described.

### —Base—

The shape, structure and size of the base are not particularly limited and may be appropriately selected depending on the intended purpose.

The material of the base is not particularly limited and may be appropriately selected depending on the intended purpose. Examples of the base include a glass base and a plastic base.

The glass base is not particularly limited and may be appropriately selected depending on the intended purpose. Examples thereof include an alkali-free glass base and a silica glass base.

The plastic base is not particularly limited and may be appropriately selected depending on the intended purpose. Examples thereof include a polycarbonate (PC) base, a polyimide (PI) base, a polyethylene terephthalate (PET) base and a polyethylene naphthalate (PEN) base.

Notably, the base is preferably pre-treated through washing using oxygen plasma, UV ozone and UV irradiation from the viewpoints of cleaning the surface thereof and improving the adhesiveness of the surface.

### —Gate Electrode-Forming Step—

The gate electrode-forming step is not particularly limited and may be appropriately selected depending on the intended purpose, so long as it is a step of forming a gate electrode on the base. Examples of the gate electrode-forming step include (i) a step of forming a film by, for example, a sputtering method or a dip coating method and patterning the film through photolithography and (ii) a step of directly forming a film having a desired shape through a printing process such as inkjetting, nanoimprinting or gravure printing.

### —Gate Insulating Layer-Forming Step—

The gate insulating layer-forming step is not particularly limited and may be appropriately selected depending on the intended purpose, so long as it is a step of forming a gate insulating layer on the gate electrode. Examples of the gate insulating layer-forming step include (i) a step of forming a film by, for example, a sputtering method or a dip coating method and patterning the film through photolithography and (ii) a step of directly forming a film having a desired shape through a printing process such as inkjetting, nanoimprinting or gravure printing. —Source Electrode and Drain Electrode-Forming Step—

The source electrode and drain electrode-forming step is not particularly limited and may be appropriately selected depending on the intended purpose, so long as it is a step of forming a source electrode and a drain electrode on the gate insulating layer so that they are spaced from each other. Examples of the source electrode and drain electrode-forming step include (i) a step of forming a film by, for example, a sputtering method or a dip coating method and patterning the film through photolithography and (ii) a step of directly forming a film having a desired shape through a printing process such as inkjetting, nanoimprinting or gravure printing.

### —Active Layer-Forming Step—

The active layer-forming step is not particularly limited and may be appropriately selected depending on the intended purpose, so long as it is a step of coating the coating liquid of the present invention for forming a metal oxide thin film to form an active layer of an oxide semiconductor on the gate insulating layer in the channel region between the source electrode and the drain electrode.

In the active layer-forming step, preferably, by appropriately adjusting the ratio [B/(A+B)] where A denotes the number of indium ions and B denotes the sum of the number of magnesium ions and the number of zinc ions in the coating liquid for forming a metal oxide thin film, the oxide semiconductor is controlled in at least one of volume resistivity, carrier mobility and carrier density. By doing so, a field effect transistor having desired characteristics (e.g., on/off ratio) can be obtained.

In the active layer-forming step, preferably, the coating liquid for forming a metal oxide thin film contains the diol and, by appropriately adjusting the mixing ratio of the glycol ether and the diol contained in the coating liquid for forming a metal oxide thin film, the coating liquid for forming a metal oxide thin film is controlled in viscosity. By doing so, the coating liquid is excellent in coatability and a field effect transistor having a channel formed in a good state can be obtained.

The method for coating the coating liquid for forming a metal oxide thin film to form an oxide semiconductor is not particularly limited and may be appropriately selected depending on the intended purpose. Examples thereof include a method in which the base is coated with the coating liquid for forming a metal oxide thin film, followed by drying and then baking.

The coating method is not particularly limited and may be appropriately selected depending on the intended purpose. Examples thereof include a screen printing method, a roll coating method, a dip coating method, a spin coating method, an inkjet method and a nanoimprint method. Among them, the inkjet method and the nanoimprint method are preferred since they can control the amount of the coating liquid attached. As a result, for example, the width of the channel can be formed as designed in the production of a field effect transistor; in other wards, an active layer having a desired shape can be obtained.

The conditions under which the drying is performed are not particularly limited and may be appropriately selected depending on the intended purpose, so long as volatile components in the coating liquid for forming a metal oxide thin film can be removed. Notably, in the drying, the volatile components do not have to be removed completely; i.e., the volatile components may be removed to such an extent that they do not inhibit the baking.

The temperature at which the baking is performed is not particularly limited and may be appropriately selected depending on the intended purpose. It is preferably 300° C. to 600° C.

In the first production method, the order in which the source electrode and drain electrode-forming step and the active layer-forming step are performed may be any order; i.e., the active layer-forming step may be performed after the source electrode and drain electrode-forming step, or the source electrode and drain electrode-forming step may be performed after the active layer-forming step.

In the first production method, when the active layer-forming step is performed after the source electrode and drain electrode-forming step, a field effect transistor of a bottom gate/bottom contact type can be produced.

In the first production method, when the source electrode and drain electrode-forming step is performed after the active layer-forming step, a field effect transistor of a bottom gate/top contact type can be produced.

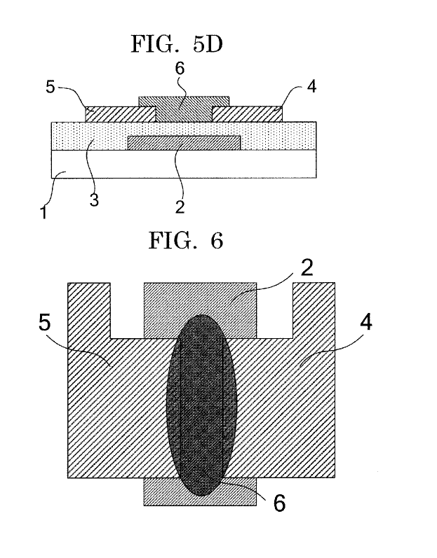

Referring to FIGS. 5A to 5D, next will be described a method for producing a field effect transistor of a bottom gate/bottom contact type.

First, a conductive film made of, for example, aluminum is formed on a base 1 (e.g., a glass substrate) by, for example, a sputtering method, and the conductive film is patterned through etching to form a gate electrode 2 (FIG. 5A).

Next, a gate insulating layer 3 made of, for example, SiO₂ is formed on the gate electrode 2 and the base 1 by, for example, a sputtering method so as to cover the gate electrode 2 (FIG. 5B).

Next, a conductive film made of, for example, ITO is formed on the gate insulating layer 3 by, for example, a sputtering method, and the conductive film is patterned through etching to form a source electrode 4 and a drain electrode 5 (FIG. 5C).

Next, the coating liquid for forming a metal oxide thin film is coated on the gate insulating layer 3 by, for example, an inkjet method so as to cover a channel region formed between the source electrode 4 and the drain electrode 5, followed by thermally treating, to thereby form an active layer 6 of an oxide semiconductor (FIG. 5D).

Through the above procedure, a field effect transistor is produced.

### <Second Production Method>

The above second production method will next be described.

### —Base—

The base is not particularly limited and may be appropriately selected depending on the intended purpose. Examples thereof include the bases which are the same as exemplified in the first production method.

### —Source Electrode and Drain Electrode-Forming Step—

The source electrode and drain electrode-forming step is not particularly limited and may be appropriately selected depending on the intended purpose, so long as it is a step of forming a source electrode and a drain electrode on the base so that they are spaced from each other. Examples of the source electrode and drain electrode-forming step include the steps which are the same as exemplified as the source electrode and drain electrode-forming step of the first production method.

### —Active Layer-Forming Step—

The active layer-forming step is not particularly limited and may be appropriately selected depending on the intended purpose, so long as it is a step of coating the coating liquid of the present invention for forming a metal oxide thin film to form an active layer of an oxide semiconductor on the base in the channel region between the source electrode and the drain electrode.

The method for coating the coating liquid for forming a metal oxide thin film to form the oxide semiconductor is not particularly limited and may be appropriately selected depending on the intended purpose. Examples of the active layer-forming step include the steps which are the same as exemplified as the active layer-forming step of the first production method.

In the active layer-forming step, preferably, by appropriately adjusting the ratio [B/(A+B)] where A denotes the number of indium ions and B denotes the sum of the number of magnesium ions and the number of zinc ions in the coating liquid for forming a metal oxide thin film, the oxide semiconductor is controlled in at least one of volume resistivity, carrier mobility and carrier density. By doing so, a field effect transistor having desired characteristics (e.g., on/off ratio) can be obtained.

In the active layer-forming step, preferably, the coating liquid for forming a metal oxide thin film contains the diol and, by appropriately adjusting the mixing ratio of the glycol ether and the diol contained in the coating liquid for forming a metal oxide thin film, the coating liquid for forming a metal oxide thin film is controlled in viscosity. By doing so, the coating liquid is excellent in coatability and a field effect transistor having a channel in a good state can be obtained.

### —Gate Insulating Layer-Forming Step—

The gate insulating layer-forming step is not particularly limited and may be appropriately selected depending on the intended purpose, so long as it is a step of forming a gate insulating layer on the active layer. Examples of the gate insulating layer-forming step include the steps which are the same as exemplified as the gate insulating layer-forming step of the first production method.

### —Gate Electrode-Forming Step—

The gate electrode-forming step is not particularly limited and may be appropriately selected depending on the intended purpose, so long as it is a step of forming a gate electrode on the gate insulating layer. Examples of the gate electrode-forming step include the steps which are the same as exemplified as the gate electrode-forming step of the first production method.

In the second production method, the order in which the source electrode and drain electrode-forming step and the active layer-forming step are performed may be any order; i.e., the active layer-forming step may be performed after the source electrode and drain electrode-forming step, or the source electrode and drain electrode-forming step may be performed after the active layer-forming step.

In the second production method, when the active layer-forming step is performed after the source electrode and drain electrode-forming step, a field effect transistor of a top gate/bottom contact type can be produced.

In the second production method, when the source electrode and drain electrode-forming step is performed after the active layer-forming step, a field effect transistor of a top gate/top contact type can be produced.

### [Another Method for Producing a Field Effect Transistor]

As an embodiment of another method for producing a field effect transistor different from that of the present invention, there is exemplified a method for producing a field effect transistor which is the same as the method of the present invention for producing a field effect transistor except that the above another coating liquid for forming a metal oxide thin film is used instead of the coating liquid of the present invention for forming a metal oxide thin film.

### EXAMPLES

The present invention will next be described by way of Examples, which should not be construed as limiting the present invention thereto.

### Example 1

### <Preparation of Coating Liquid for Forming a Metal Oxide Thin Film>

First, 3.55 g of indium nitrate (In(NO₃)₃.3H₂O) and 1.28 g of magnesium nitrate (Mg(NO₃)₂.6H₂O) were weighed and placed in a beaker. Then, 80 mL of ethylene glycol monomethyl ether was added to the beaker, followed by mixing and dissolving at room temperature, to thereby prepare a coating liquid for forming a metal oxide thin film.

Tables 2-1 and 2-2 show the ratio [B/(A+B)](where A denotes the number of indium ions and B denotes the sum of the number of magnesium ions and the number of zinc ions), the amount of the glycol ether (% by mass), the amount of the metal salts per 1 L of the diol and the glycol ether, and the ratio (C)/(A) (%) (where A denotes the number of indium ions and C denotes the sum of the number of aluminum ions and the number of gallium ions) in the obtained coating liquid for forming a metal oxide thin film.

### <Production of Field Effect Transistor>

### —Formation of Gate Electrode—

Through DC sputtering, a molybdenum film was formed on a glass substrate so as to have a thickness of about 100 nm. Subsequently, the thus-formed film was coated with a photoresist, followed by prebaking, exposing by an exposing device, and developing, to thereby form a resist pattern having the same pattern as that of a gate electrode to be formed. Furthermore, etching was performed using an etchant containing phosphoric acid, nitric acid and acetic acid, to thereby remove the regions of the molybdenum film where the resist pattern had not been formed. Thereafter, the resist pattern was removed to form a gate electrode.

### —Formation of Gate Insulating Layer—

Through RF sputtering, a SiO₂ film was formed on the gate electrode and the glass substrate so as to have a thickness of about 300 nm. Subsequently, the thus-formed film was coated with a photoresist, followed by prebaking, exposing by an exposing device, and developing, to thereby form a resist pattern having the same pattern as that of a gate insulating layer to be formed. Furthermore, etching was performed using buffered hydrofluoric acid, to thereby remove the regions of the SiO₂ film where the resist pattern had not been formed. Thereafter, the resist pattern was removed to form a gate insulating layer.

### —Formation of Source Electrode and Drain Electrode—

Through DC sputtering, an ITO film (In₂O₃.SnO₂ (5% by mass)) as a transparent conductive film was formed on the formed gate insulating layer so as to have a thickness of about 100 nm. Subsequently, the thus-formed ITO film was coated with a photoresist, followed by prebaking, exposing by an exposing device, and developing, to thereby form a resist pattern having the same pattern as that of a source electrode and a drain electrode to be formed. Furthermore, etching was performed using an oxalic acid-based etchant, to thereby remove the regions of the ITO film where the resist pattern had not been formed. Thereafter, the resist pattern was removed to form a source electrode and a drain electrode of the ITO film. Here, the channel width defined as the width of the source electrode was set to 50 μm, and the channel length defined as the length between the source electrode and the drain electrode was set to 10 μm.

### —Formation of Active Layer—

Using an inkjet device, the coating liquid for forming a metal oxide thin film was coated on the channel between the source electrode and the drain electrode.

The substrate was dried for 10 min on a hot plate heated to 120° C. and then baked in an air atmosphere at 500° C. for 1 hour. In addition, the substrate was annealed in an air atmosphere at 300° C. for 3 hours to thereby obtain an active layer. The thickness of the obtained active layer in the channel was found to be about 20 nm.

Through the above procedure, a field effect transistor was produced.

### <Evaluation>

—State where Channel was Formed (Coatability)—

By observing with an optical microscope spread of the coating liquid for forming a metal oxide thin film when it had been coated using the inkjet device in the production of the field effect transistor, the state where the channel had been formed was evaluated according to the following evaluation criteria. The results are shown in Tables 3-1 and 3-2.

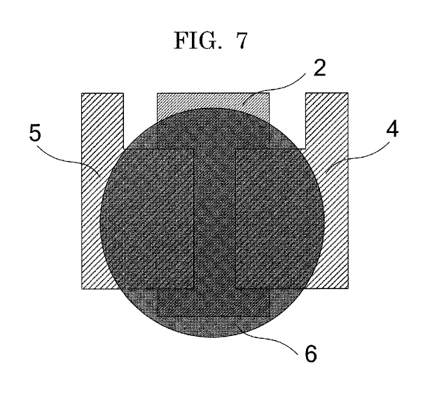

A: The active layer spread within the space between the source electrode and the drain electrode, and did not exceed the gate electrode (see FIG. 6).
B: The active layer spread out of the space between the source electrode and drain electrode, and exceeded the gate electrode (see FIG. 7).

### —Volume Resistivity—

Using semiconductor parameter analyzer 4156C (product of Agilent Technologies, Co.), a voltage of 0 V to ±20 V was applied to between the source electrode and the drain electrode of the obtained field effect transistor, and the current was measured by the two-terminal method to measure the volume resistivity of the active layer. The results are shown in Tables 3-1 and 3-2.

—Carrier Mobility and on/Off Ratio—

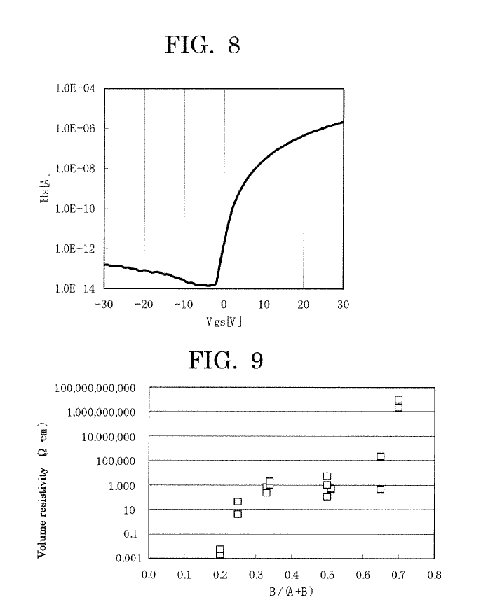

Using a semiconductor parameter analyzer (product of Agilent Technologies, Co., semiconductor parameter analyzer 4156C), the field effect transistor produced in Example 1 was measured to obtain the relationship between gate voltage Vgs and source-drain current Ids observed when the source-drain voltage Vds was set to 20 V. The results are shown in the graph of FIG. 8. It was found from FIG. 8 that good transistor characteristics were obtained.

The carrier mobility was calculated in the saturated region, and the on/off ratio was also calculated. Notably, the on value of the on/off ratio was the Ids value at 30 V. The results are shown in Table 3-1 and 3-2.

### Examples 2 to 35 and Referential Example 1

### <Preparation of Coating Liquid for Forming a Metal Oxide Thin Film>

The procedure of Example 1 was repeated, except that the formulation of the coating liquid for forming a metal oxide thin film was changed as described in Tables 1-1 and 1-2, to thereby prepare coating liquids for forming a metal oxide thin film of Examples 2 to 35 and Referential Example 1.

Tables 2-1 and 2-2 show the ratio [B/(A+B)], the amount of the glycol ether (% by mass), the amount of the metal salts per 1 L of the diol and the glycol ether, and the ratio (C)/(A) (%) (where A denotes the number of indium ions and C denotes the sum of the number of aluminum ions and the number of gallium ions) in the obtained coating liquid for forming a metal oxide thin film.

### <Production and Evaluation of Field Effect Transistor>

The procedure of Example 1 was repeated, except that each of the coating liquids of Examples 2 to 23 and 28 to 35 was used, to thereby produce and evaluate a field effect transistor. The results are shown in Table 3-1 and 3-2.

### <Relationship Between Volume Resistivity and [B/(A+B)]>

FIG. 9 shows the values of volume resistivity against the ratio [B/(A+B)] in each of the coating liquids of Examples 1 to 27 (where A denotes the number of indium ions and B denotes the sum of the number of magnesium ions and the number of zinc ions). As is clear from FIG. 9, it was confirmed that the baked oxide semiconductor thin film could be controlled in volume resistivity by controlling the ratio [B/(A+B)] of the coating liquid for forming a metal oxide thin film.

### Comparative Example 1

### <Preparation of Coating Liquid for Forming a Metal Oxide Thin Film>

For evaluating the formulation of the liquid described in JP-A No. 2009-177149, 3.55 g of indium nitrate and 1.26 g of magnesium nitrate were added to a mixture containing 40 mL of water and 40 mL of ethanol. The resultant mixture was mixed for dissolution to prepare a coating liquid for forming a metal oxide thin film.

### <Production and Evaluation of Field Effect Transistor>

The thus-prepared coating liquid for forming a metal oxide thin film was used to produce a field effect transistor in the same manner as in Example 1. However, the coating liquid for forming a metal oxide thin film was poor in coatability and thus the state where the channel was formed was insufficient, resulting in that the field effect transistor could not be evaluated.

### Comparative Example 2

### <Production of Coating Liquid for Forming a Thin Film>

For evaluating the coating liquid for forming a thin film described in JP-A No. 06-96619, 3.55 g of indium nitrate and 0.26 g of magnesium nitrate were added to a mixture containing 4.0 mL of acetylacetone and 0.63 mL of glycerin, and the resultant mixture was mixed for dissolution at room temperature, to thereby prepare a coating liquid for forming a thin film.

### <Production and Evaluation of Field Effect Transistor>

Although the obtained coating liquid for forming a thin film was used for forming a field effect transistor in the same manner as in Example 1, the solvent was dried too rapidly thereby causing clogging of the inkjet device. As a result, the inkjet device could not discharge the coating liquid for forming a thin film. Thus, a field effect transistor could not be produced nor evaluated.

TABLE 1-1

| | | | | | | Material | | | | | |
|---|---|---|---|---|---|---|---|---|---|---|---|
| | | Material A | | Material B | | C | | Diol | | Glycol ether | |
| | | Name | (g) | Name | (g) | Name | (g) | Name | mL | Name | mL |
| Ex. | 1 | Indium | 3.55 | Magnesium | 1.28 | | | | | Ethylene | 80 |
| | 2 | nitrate | 3.55 | nitrate | 0.85 | | | 1,2- | 40 | glycol | 40 |
| | 3 | | 3.55 | | 1.28 | | | Propane | 50 | mono- | 30 |
| | 4 | | 3.55 | | 2.56 | | | diol | 60 | methyl | 20 |
| | 5 | | 3.55 | | 4.76 | | | | 70 | ether | 10 |
| | 6 | | 3.55 | | 1.28 | | | Diethylene | 40 | | 40 |
| | | | | | | | | glycol | | | |
| | 7 | | 3.55 | | 1.28 | | | 1,2- | 40 | | 40 |
| | | | | | | | | Ethane | | | |
| | | | | | | | | diol | | | |
| | 8 | | 3.55 | | 1.28 | | | 1,3 | 40 | | 40 |
| | | | | | | | | Butane | | | |
| | | | | | | | | diol | | | |
| | 9 | | 3.55 | | 1.28 | | | 1,2- | 40 | | 40 |
| | 10 | | 3.55 | | 1.28 | | | Propane | 40 | Ethylene | 40 |
| | | | | | | | | diol | | glycol | |
| | | | | | | | | | | mono- | |
| | | | | | | | | | | propyl | |
| | | | | | | | | | | ether | |
| | 11 | | 3.55 | | 1.28 | | | | 40 | Ethylene | 40 |
| | | | | | | | | | | glycol | |
| | | | | | | | | | | mono- | |
| | | | | | | | | | | iso- | |
| | | | | | | | | | | propyl | |
| | | | | | | | | | | ether | |
| | 12 | | 3.55 | | 1.28 | | | | 40 | Ethylene | 40 |
| | | | | | | | | | | glycol | |
| | | | | | | | | | | mono- | |
| | | | | | | | | | | butyl | |
| | | | | | | | | | | ether | |
| | 13 | | 3.55 | | 1.28 | | | | 40 | Ethylene | 40 |
| | | | | | | | | | | glycol | |
| | | | | | | | | | | mono- | |
| | | | | | | | | | | iso- | |
| | | | | | | | | | | butyl | |
| | | | | | | | | | | ether | |
| | 14 | | 3.55 | | 1.28 | | | | 40 | Ethylene | 40 |
| | 15 | | 3.55 | Zinc | 1.49 | | | | 40 | glycol | 40 |
| | 16 | | 3.55 | nitrate | 0.99 | | | | 40 | mono- | 40 |
| | 17 | | 3.55 | | 2.97 | | | | 40 | methyl | 40 |
| | 18 | | 3.55 | | 5.52 | | | | 40 | ether | 40 |

TABLE 1-2

| | | Material A | | Material B | | Material C | | Diol | | Glycol ether | |
|---|---|---|---|---|---|---|---|---|---|---|---|
| | | Name | (g) | Name | (g) | Name | (g) | Name | mL | Name | mL |
| Ex. | 19 | Indium | 3.37 | Magnesium | 1.28 | Aluminum | 0.19 | 1,2- | 40 | Ethylene | 40 |
| | | nitrate | | nitrate | | nitrate | | Propane | | glycol | |
| | 20 | | 3.37 | | 1.28 | Gallium | 0.15 | diol | 40 | mono- | 40 |
| | | | | | | nitrate | | | | methyl | |
| | 21 | | 3.37 | Zinc | 2.97 | Aluminum | 0.19 | | 40 | ether | 40 |
| | | | | nitrate | | nitrate | | | | | |
| | 22 | | 3.37 | | 2.97 | Gallium | 0.15 | | 40 | | 40 |
| | | | | | | nitrate | | | | | |
| | 23 | | 3.55 | Magnesium | 1.28 | | | | 40 | | 40 |
| | | | | nitrate | | | | | | | |
| | | | | Zinc | 1.49 | | | | | | |
| | | | | nitrate | | | | | | | |
| | 24 | | 3.55 | Magnesium | 0.64 | | | | 40 | | 40 |
| | 25 | | 3.55 | nitrate | 5.96 | | | | 40 | | 40 |
| | 26 | | 3.55 | Zinc | 0.74 | | | | 40 | | 40 |
| | 27 | | 3.55 | nitrate | 6.92 | | | | 40 | | 40 |
| | 28 | Indium | 6.80 | Magnesium | 1.28 | | | | 40 | | 40 |
| | | sulfate | | nitrate | | | | | | | |
| | 29 | Indium | 2.93 | | 1.28 | | | | 40 | | 40 |
| | | chloride | | | | | | | | | |
| | 30 | Indium | 6.80 | Zinc | 1.49 | | | | 40 | | 40 |
| | | sulfate | | nitrate | | | | | | | |
| | 31 | Indium | 2.93 | | 1.49 | | | | 40 | | 40 |
| | | chloride | | | | | | | | | |
| | 32 | Indium | 3.55 | Magnesium | 1.23 | | | | 40 | | 40 |
| | | nitrate | | sulfate | | | | | | | |
| | 33 | | 3.55 | Magnesium | 1.02 | | | | 40 | | 40 |
| | | | | chloride | | | | | | | |
| | 34 | | 3.55 | Zinc | 1.44 | | | | 40 | | 40 |
| | | | | sulfate | | | | | | | |
| | 35 | | 3.55 | Zinc | 6.8 | | | | 40 | | 40 |
| | | | | chloride | | | | | | | |
| Ref. | 1 | | 3.55 | Magnesium | 1.28 | | | 1,2- | 80 | | |
| Ex. | | | | nitrate | | | | Propane | | | |
| | | | | | | | | diol | | | |

| | | | | | |
|---|---|---|---|---|---|
| Comp. | 1 | 3.55 | Magnesium | 1.26 | (*1) |
| Ex. | 2 | 3.55 | nitrate | 0.26 | (*2) |

In Tables 1-1 and 1-2, the indium nitrate is In(NO₃)₃.3 H₂O, the indium sulfate is In₂(SO₄)₃.9H₂O, the indium chloride is InCl₃.4H₂O, the magnesium nitrate is Mg(NO₃)₂.6H₂O, the magnesium sulfate is MgSO₄.7H₂O, the magnesium chloride is MgCl₂.6H₂O, the zinc nitrate is Zn(NO₃)₂.6H₂O, the zinc sulfate is ZnSO₄.7H₂O, the zinc chloride is ZnCl₂.H₂O (zinc chloride anhydrate), the aluminum nitrate is Al(NO₃)₃.9H₂O and the gallium nitrate is Ga(NO₃)₃.3H₂O.

In Table 1-2, (*1) means a mixture containing 40 mL of water and 40 mL of ethanol, and (*2) means a mixture containing 4.0 mL of acetylacetone and 0.63 mL of glycerin.

TABLE 2-1

| | | | | Amount | |
|---|---|---|---|---|---|
| | | | | of metal | Ratio C/A (%) of sum C of |
| | | | Amount of | salts per 1 L | number of aluminum ions |
| | | | glycol | of diol and | and number of gallium |
| | | B/(A + | ether (% | glycol ether | ions to number A of |
| | | B) | by mass) | (mol) | indium ions |
| Ex. | 1 | 0.33 | 94.1 | 0.19 | 0 |
| | 2 | 0.25 | 45.7 | 0.17 | 0 |
| | 3 | 0.33 | 33.8 | 0.19 | 0 |
| | 4 | 0.50 | 22.0 | 0.25 | 0 |
| | 5 | 0.65 | 10.6 | 0.36 | 0 |
| | 6 | 0.33 | 44.0 | 0.19 | 0 |
| | 7 | 0.33 | 44.0 | 0.19 | 0 |
| | 8 | 0.33 | 46.1 | 0.19 | 0 |
| | 9 | 0.33 | 44.4 | 0.19 | 0 |
| | 10 | 0.33 | 43.9 | 0.19 | 0 |
| | 11 | 0.33 | 43.8 | 0.19 | 0 |
| | 12 | 0.33 | 43.7 | 0.19 | 0 |
| | 13 | 0.33 | 43.5 | 0.19 | 0 |
| | 14 | 0.33 | 45.4 | 0.19 | 0 |
| | 15 | 0.33 | 45.3 | 0.19 | 0 |
| | 16 | 0.25 | 45.6 | 0.17 | 0 |
| | 17 | 0.50 | 44.5 | 0.25 | 0 |
| | 18 | 0.65 | 43.3 | 0.36 | 0 |
| | 19 | 0.34 | 45.4 | 0.19 | 5 |
| | 20 | 0.34 | 45.4 | 0.19 | 5 |
| | 21 | 0.51 | 44.5 | 0.25 | 5 |
| | 22 | 0.51 | 44.6 | 0.25 | 5 |
| | 23 | 0.50 | 44.6 | 0.25 | 0 |
| | 24 | 0.20 | 45.8 | 0.16 | 0 |
| | 25 | 0.70 | 43.1 | 0.42 | 0 |
| | 26 | 0.20 | 45.7 | 0.16 | 0 |
| | 27 | 0.70 | 42.6 | 0.42 | 0 |

TABLE 2-2

| | | | | Amount | Ratio C/A (%) |
|---|---|---|---|---|---|
| | | | | of metal | of sum C of number |
| | | | Amount of | salts per 1 L | of aluminum ions |
| | | | glycol | of diol and | and number of gallium |
| | | B/(A + | ether (% | glycol ether | ions to number A of |
| | | B) | by mass) | (mol) | indium ions |
| Ex. | 28 | 0.33 | 43.8 | 0.19 | 0 |
| | 29 | 0.33 | 45.8 | 0.19 | 0 |
| | 30 | 0.33 | 43.7 | 0.19 | 0 |
| | 31 | 0.33 | 45.7 | 0.19 | 0 |
| | 32 | 0.33 | 45.5 | 0.19 | 0 |
| | 33 | 0.33 | 45.6 | 0.19 | 0 |
| | 34 | 0.33 | 45.4 | 0.19 | 0 |
| | 35 | 0.33 | 42.7 | 0.19 | 0 |
| Ref. | 1 | 0.33 | 0.0 | 0.19 | 0 |
| Ex. | | | | | |
| Comp. | 1 | 0.33 | 0.0 | — | 0 |
| Ex. | 2 | 0.09 | 0.0 | — | 0 |

TABLE 3-1

| | | State where | Volume | Carrier | |
|---|---|---|---|---|---|
| | | channel was | resistivity | mobility | |
| | | formed | (Ωcm) | (cm²/Vs) | on/off ratio |
| Ex. | 1 | A | 4 × 10² | 0.18 | 6.5 × 10⁷ |
| | 2 | A | 4 × 10¹ | 0.3 | 1.5 × 10⁸ |
| | 3 | A | 6 × 10² | 0.24 | 1.2 × 10⁸ |
| | 4 | A | 5 × 10³ | 0.08 | 7.2 × 10⁶ |
| | 5 | A | 2 × 10⁵ | 0.003 | 3.2 × 10⁵ |
| | 6 | A | 4 × 10² | 0.24 | 1.0 × 10⁸ |
| | 7 | A | 4 × 10² | 0.2 | 8.8 × 10⁷ |
| | 8 | A | 4 × 10² | 0.18 | 8.5 × 10⁷ |
| | 9 | A | 4 × 10² | 0.19 | 8.6 × 10⁷ |
| | 10 | A | 6 × 10² | 0.25 | 1.1 × 10⁸ |
| | 11 | A | 3 × 10² | 0.15 | 6.0 × 10⁷ |
| | 12 | A | 5 × 10² | 0.22 | 9.4 × 10⁷ |
| | 13 | A | 5 × 10² | 0.21 | 9.0 × 10⁷ |
| | 14 | A | 6 × 10² | 0.23 | 1.0 × 10⁸ |
| | 15 | A | 2 × 10² | 0.83 | 1.4 × 10⁸ |
| | 16 | A | 4 × 10⁰ | 0.54 | 1.5 × 10⁸ |
| | 17 | A | 1 × 10² | 0.96 | 1.8 × 10⁸ |
| | 18 | A | 4 × 10² | 0.2 | 1.5 × 10⁵ |
| | 19 | A | 1 × 10³ | 0.14 | 5.8 × 10⁷ |
| | 20 | A | 2 × 10³ | 0.16 | 7.1 × 10⁷ |
| | 21 | A | 4 × 10² | 0.71 | 7.7 × 10⁷ |
| | 22 | A | 5 × 10² | 0.63 | 6.5 × 10⁷ |
| | 23 | A | 1 × 10³ | 0.16 | 7.4 × 10⁷ |

TABLE 3-2

| | | State where | Volume | | |
|---|---|---|---|---|---|
| | | channel was | resistivity | Carrier mobility | |
| | | formed | (Ωcm) | (cm²/Vs) | on/off ratio |
| Ex. | 28 | A | 5 × 10² | 0.24 | 8.5 × 10⁷ |
| | 29 | A | 4 × 10² | 0.17 | 8.8 × 10⁷ |
| | 30 | A | 3 × 10² | 0.19 | 9.1 × 10⁷ |
| | 31 | A | 6 × 10² | 0.21 | 7.5 × 10⁷ |
| | 32 | A | 4 × 10² | 0.2 | 9.5 × 10⁷ |
| | 33 | A | 4 × 10² | 0.18 | 7.4 × 10⁷ |
| | 34 | A | 5 × 10² | 0.21 | 9.3 × 10⁷ |
| | 35 | A | 4 × 10² | 0.22 | 1.0 × 10⁸ |
| Ref. Ex. | 1 | A | 7 × 10² | 0.26 | 1.1 × 10⁸ |
| Comp. | 1 | B | — | — | — |
| Ex. | 2 | — | — | — | — |

The coating liquids of the present invention of Examples 1 to 23 and 28 to 35 and the coating liquid of Referential Example 1 were excellent in coatability and could provide good results as to the state where the channel was formed. Moreover, in the field effect transistors using, in their active layer, the oxide semiconductors formed through coating of the coating liquids for forming a metal oxide thin film, the active layer had a volume resistivity suitable for the active layer of the field effect transistor and exhibited high carrier mobility and high on/off ratio. Thus, these field effect transistors showed good transistor characteristics.

In Comparative Example 1, the coating liquid for forming an oxide semiconductor thin film was poor in coatability and the channel was insufficiently formed. Thus, the field effect transistor could not be evaluated.

The metal oxide thin film-coating liquids of Examples 24 and 26 were excellent in coatability. As shown in Table 4 below, the formed metal oxide thin films had a low volume resistivity, and were suitable metal oxide thin films as, for example, transparent conductive thin films.

The metal oxide thin film-coating liquids of Examples 25 and 27 were excellent in coatablity. As shown in Table 4 below, the formed metal oxide thin films had a relatively high volume resistivity, and were suitable metal oxide thin films as, for example, antistatic thin films.

TABLE 4

| | | Volume |
|---|---|---|
| | | resistivity |
| | | (Ωcm) |
| Ex. | 24 | 2 × 10⁻³ |
| | 25 | 2 × 10⁹ |
| | 26 | 5 × 10⁻³ |
| | 27 | 1 × 10⁹ |

Notably, the volume resistivity shown in Table 4 was measured in the same manner as in the measurement of the volume resistivity in Example 1.

### Example 36

The mixing ratio of the glycol ether and the diol was changed to control the metal oxide thin film-coating liquid in viscosity.

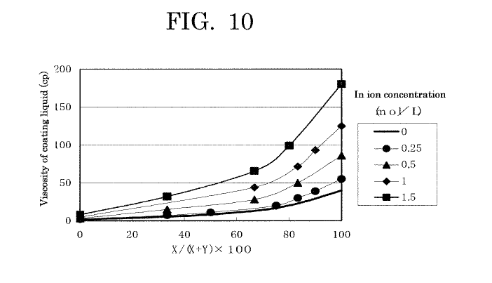

Specifically, ethylene glycol monomethyl ether (viscosity: about 1.6 cp), 1,2-propanediol (viscosity: about 40 cp), indium nitrate (In(NO₃)₃.3H₂O) and magnesium nitrate (Mg(NO₃)₂.6H₂O) were used to prepare metal oxide thin film-coating liquids. In this preparation, the mixing ratio of indium nitrate and magnesium nitrate in the metal oxide thin film-coating liquid was adjusted so that the number of In ions:the number of Mg ions was 2:1 and that the concentration of In ions was 0 mol/L, 0.25 mol/L, 0.5 mol/L, 1 mol/L or 1.5 mol/L. Then, the mixing ratio of ethylene glycol monomethyl ether (X mL) and 1,2-propanediol (Y mL) was variously changed. The results are shown in FIG. 10. It was confirmed that the metal oxide thin film-coating liquids having different In ion concentrations could be controlled in viscosity by changing the mixing ratio of the glycol ether and the diol contained therein.

### REFERENCE SIGNS LIST

1 Base
2 Gate electrode
3 Gate insulating layer
4 Source electrode
5 Drain electrode
6 Active layer

1. A coating liquid for forming a metal oxide thin film, the coating liquid comprising:
an inorganic indium compound;
at least one of an inorganic magnesium compound and an inorganic zinc compound; and
a glycol ether.

2. The coating liquid for forming a metal oxide thin film according to claim 1,
wherein the inorganic indium compound is at least one selected from the group consisting of indium nitrate, indium sulfate and indium chloride,
wherein the inorganic magnesium compound is at least one selected from the group consisting of magnesium nitrate, magnesium sulfate and magnesium chloride, and
wherein the inorganic zinc compound is at least one selected from the group consisting of zinc nitrate, zinc sulfate and zinc chloride.

3. The coating liquid for forming a metal oxide thin film according to claim 1, wherein the coating liquid for forming a metal oxide thin film satisfies the following expression (1):
0.25≦[B/(A+B)]≦0.65 Expression (1)
where A denotes the number of indium ions and B denotes the sum of the number of magnesium ions and the number of zinc ions in the coating liquid for forming a metal oxide thin film.

4. The coating liquid for forming a metal oxide thin film according to claim 1, further comprising a diol.

5. The coating liquid for forming a metal oxide thin film according to claim 1, further comprising at least one of an inorganic aluminum compound and an inorganic gallium compound.

6. A metal oxide thin film obtained by a method comprising:
coating a coating object with a coating liquid for forming a metal oxide thin film;
drying the coating object which has been coated with the coating liquid; and
baking the dried coating object to form the metal oxide thin film thereover,
wherein the coating liquid for forming a metal oxide thin film comprises:
an inorganic indium compound;
at least one of an inorganic magnesium compound and an inorganic zinc compound; and
a glycol ether.

7. A field effect transistor comprising:
a gate electrode configured to apply gate voltage,
a source electrode and a drain electrode which are configured to take out current,
an active layer formed of an oxide semiconductor and disposed between the source electrode and the drain electrode, and
a gate insulating layer formed between the gate electrode and the active layer,
wherein the oxide semiconductor is formed through coating of a coating liquid for forming a metal oxide thin film,
wherein the coating liquid for forming a metal oxide thin film comprises:
an inorganic indium compound;
at least one of an inorganic magnesium compound and an inorganic zinc compound; and
a glycol ether.

8-11. (canceled)
